(19) United States
(12) Patent Application Publication
(10) Pub. No.: US 2024/0106474 A1
(43) Pub. Date: Mar. 28, 2024

(54) MIXER SECOND-ORDER INPUT INTERCEPT POINT (IIP2) CALIBRATION USING A SINGLE TONE GENERATOR AND/OR REVERSE FEEDTHROUGH

(71) Applicant: QUALCOMM Incorporated, San Diego, CA (US)

(72) Inventors: Gary Lee BROWN, Jr., Carlsbad, CA (US); Chirag Dipak PATEL, San Diego, CA (US); Prakash THOPPAY EGAMBARAM, San Diego, CA (US)

(21) Appl. No.: 17/934,455

(22) Filed: Sep. 22, 2022

(51) Int. Cl. H04B 1/16; H03D 7/12

(52) U.S. Cl. CPC H04B 1/16; H03D 7/12

(57) ABSTRACT

Methods and apparatus for calibration of a second-order input intercept point (IIP2) of a mixer, such as a mixer in a wireless receive chain. One example circuit for mixer IIP2 calibration generally includes a first receive chain comprising a first mixer and a single tone generator having an output coupled to an input of the first mixer and configured to generate a calibration signal having a single baseband tone. One example method of mixer IIP2 calibration generally includes generating a calibration signal comprising a single baseband tone, applying the calibration signal to an input of a mixer, such that the mixer generates a differential tone at an output of the mixer, and adjusting the mixer to minimize a power of the differential tone at the output of the mixer.

### TECHNICAL FIELD

Certain aspects of the present disclosure generally relate to electronic circuits and, more particularly, to techniques and apparatus for calibrating a mixer.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, Fifth Generation (5G) New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include a radio receiver with a mixer, which may be used, for example, to downconvert a wirelessly received radio frequency (RF) signal to a baseband signal for signal processing (e.g., filtering, analog-to-digital converting, and demodulating) before the signal is interpreted.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include decreased mixer second-order input intercept point (IIP2) calibration time and/or reduced lateral area (e.g., footprint) of the circuitry for mixer IIP2 calibration.

Certain aspects of the present disclosure generally relate to calibration of a mixer (e.g., in a wireless receiver) for IIP2 to reduce second-order intermodulation distortion (IMD2).

Certain aspects of the present disclosure provide a circuit for mixer IIP2 calibration. The circuit generally includes a first receive chain comprising a first mixer and a single tone generator having an output coupled to an input of the first mixer and configured to generate a calibration signal having a single baseband tone.

Certain aspects of the present disclosure provide a wireless device. The wireless device generally includes a first receive chain comprising a first mixer and a single tone generator having an output coupled to an input of the first mixer and configured to generate a calibration signal having a single baseband tone. The wireless device also includes at least one antenna coupled to an input of the first receive chain, an analog-to-digital converter (ADC) coupled to an output of the first receive chain, and a processor having an input coupled to an output of the ADC. The first mixer is configured to generate a differential tone when the single tone generator applies the calibration signal to the first mixer. The processor is configured to receive a representation of the differential tone, to control the single tone generator, and to control adjustment of the first mixer to minimize a power of the representation of the differential tone.

Certain aspects of the present disclosure provide a method of mixer IIP2 calibration. The method generally includes generating a calibration signal comprising a single baseband tone, applying the calibration signal to an input of a mixer, such that the mixer generates a differential tone at an output of the mixer, and adjusting the mixer to minimize a power of the differential tone at the output of the mixer.

Certain aspects of the present disclosure provide an apparatus for wireless communication capable of mixer IIP2 calibration. The apparatus generally includes means for generating a calibration signal comprising a single baseband tone, means for applying the calibration signal to an input of a mixer, such that the mixer generates a differential tone at an output of the mixer, and means for adjusting the mixer to minimize a power of the differential tone at the output of the mixer.

Certain aspects of the present disclosure provide a circuit for mixer IIP2 calibration. The circuit generally includes a first amplifier, a first receive chain comprising a first mixer having an input coupled to an output of the first amplifier, and a second amplifier having an input coupled to the output of the first amplifier.

Certain aspects of the present disclosure provide a wireless device. The wireless device includes a first amplifier, a first receive chain comprising a first mixer having an input coupled to an output of the first amplifier, and a second amplifier having an input coupled to the output of the first amplifier. The wireless device further includes a single tone generator having an output coupled to the output of the first amplifier, to the input of the first mixer, and to the input of the second amplifier, the single tone generator being configured to generate a calibration signal having a single tone at a sum of a local oscillator (LO) frequency and a baseband frequency. The wireless device further includes a frequency synthesizer configured to generate an LO signal at the LO frequency and to apply the LO signal to an LO port of the first mixer, an analog-to-digital converter coupled to an output of the first receive chain, and a processor having an input coupled to an output of the analog-to-digital converter. The single tone generator is configured to apply the calibration signal to a radio frequency (RF) port of the first mixer; the first mixer is configured to downconvert the calibration signal based on the LO signal; the second amplifier is configured to amplify second-order intermodulation distortion (IMD2) generated by the first mixer due to the downconversion; and the processor is configured to control adjustment of the first mixer based on the amplified IMD2 to minimize the amplified IMD2.

Certain aspects of the present disclosure provide a wireless device. The wireless device includes a first amplifier, a first receive chain comprising a first mixer having an input coupled to an output of the first amplifier, and a second amplifier having an input coupled to the output of the first amplifier. The wireless device further includes at least one antenna coupled to an input of the first receive chain, an analog-to-digital converter coupled to an output of the first receive chain, and a processor having an input coupled to an output of the analog-to-digital converter. The at least one antenna is configured to receive an RF signal; the first amplifier is configured to amplify the received RF signal; the first mixer is configured to downconvert the amplified RF signal; the second amplifier is configured to amplify IMD2 generated by the first mixer due to the downconversion; and the processor is configured to control adjustment of the first mixer based on the amplified IMD2.

Certain aspects of the present disclosure provide a method of mixer IIP2 calibration. The method generally includes downconverting an RF signal with a mixer; amplifying, with a first amplifier, IMD2 generated by the mixer due to the downconversion and fed in reverse from an output port of the mixer to an RF port of the mixer; and adjusting the mixer based on the amplified IMD2 to minimize the amplified IMD2.

Certain aspects of the present disclosure provide an apparatus for wireless communication capable of mixer IIP2 calibration. The apparatus generally includes means for downconverting an RF signal, means for amplifying IMD2 generated by the means for downconverting due to the downconversion and fed through in reverse from an output port of the means for downconverting to an RF port of the means for downconverting, and means for adjusting the means for downconverting based on the amplified IMD2 to minimize the amplified IMD2.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example a base station (BS) and user equipment (UE), in which aspects of the present disclosure may be practiced.

FIG. 3 is a block diagram of an example radio frequency (RF) transceiver, in which aspects of the present disclosure may be practiced.

FIG. 4 is a block diagram of an example circuit for mixer second-order input intercept point (IIP2) calibration using a single tone generator, in which aspects of the present disclosure may be practiced.

FIG. 5 is a block diagram of an example circuit for mixer IIP2 calibration using a received radio frequency (RF) signal and amplifying second-order intermodulation distortion (IMD2) from reverse feedthrough from the mixer, in accordance with certain aspects of the present disclosure.

FIG. 6 is a block diagram of an example circuit for mixer IIP2 calibration using a single tone generator and amplifying IMD2 from reverse feedthrough from the mixer, in accordance with certain aspects of the present disclosure.

FIG. 7 is a flow diagram of example operations for mixer IIP2 calibration, in accordance with certain aspects of the present disclosure.

FIG. 8 is a flow diagram of example operations for mixer IIP2 calibration, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure relate to techniques and apparatus for mixer second-order input intercept point (IIP2) calibration. One technique involves applying a single baseband tone to an input of a mixer, such that the mixer generates a differential tone, and adjusting the mixer to minimize a power of the differential tone at the output of the mixer. Another technique involves downconverting a radio frequency (RF) signal with a mixer, amplifying second-order intermodulation distortion (IMD2) products generated by the mixer and fed in reverse from an output port of the mixer to an RF port of the mixer, and adjusting the mixer based on the amplified IMD2 products. The RF signal may be a single RF tone (e.g., comprising a local oscillator (LO) frequency plus a baseband tone) or a wirelessly received RF signal.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

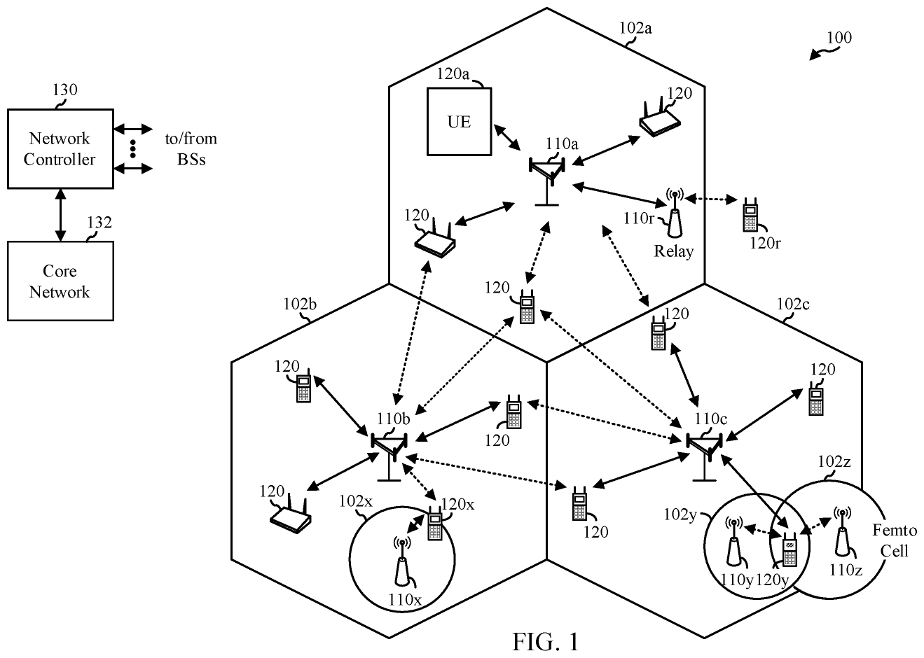

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS 110. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. ABS may support one or multiple cells.

The BSs 110 communicate with one or more user equipments (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ, UEs may be selected for simultaneous transmission on the uplink, N_{dn} UEs may be selected for simultaneous transmission on the downlink. Nᵤₚ may or may not be equal to N_{dn}, and Nᵤₚ, and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nap of antennas to achieve transmit diversity for downlink transmissions and/or receive diversity for uplink transmissions. A set Nu of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nu UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include circuitry for mixer second-order input intercept point (IIP2) calibration, as described in more detail herein.

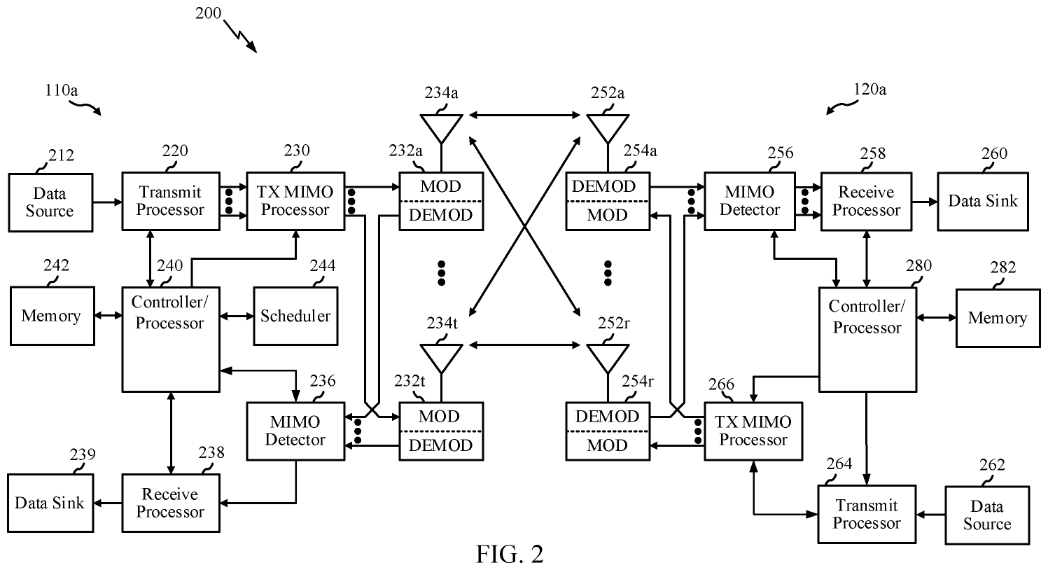

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARD) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

Antennas 252, processors 258, 264, 266, and/or controller/processor 280 of the UE 120a and/or antennas 234, processors 220, 230, 238, and/or controller/processor 240 of the BS 110a may be used to perform the various techniques and methods described herein.

In certain aspects of the present disclosure, the transceivers 232 and/or the transceivers 254 may include circuitry for mixer second-order input intercept point (IIP2) calibration, as described in more detail herein.

### Example RF Transceiver

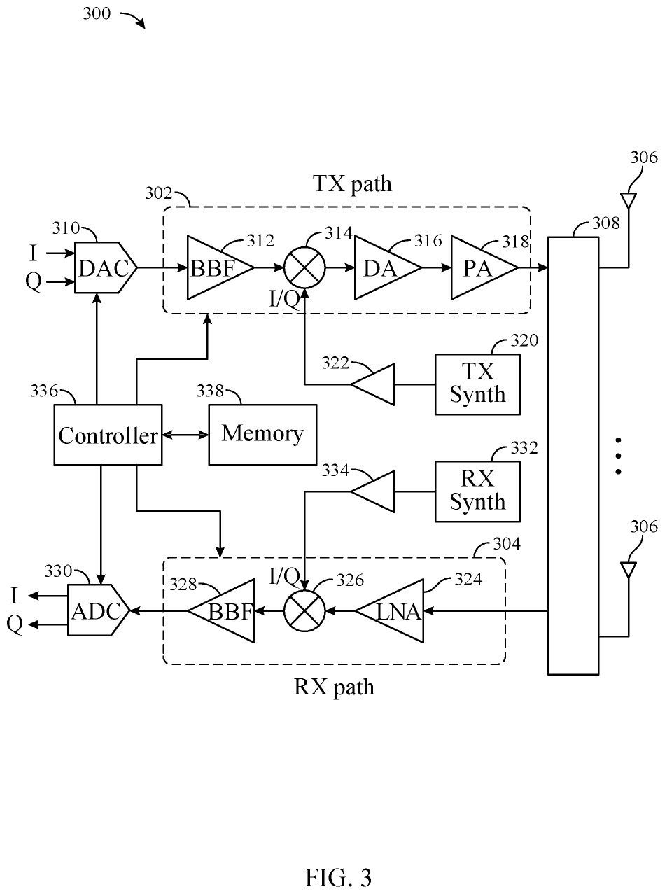

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, and a baseband filter (BBF) 328. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing.

For certain aspects, the mixer 326 may introduce second-order intermodulation distortion (IMD2) in the RX path 304. Therefore, the RF transceiver circuit 300 may also include circuitry for second-order input intercept point (IIP2) calibration of the mixer 326, as described below.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency multiplier, such as a frequency doubler, that is driven by an oscillator (e.g., a VCO) in the frequency synthesizer.

A controller 336 (e.g., controller/processor 280 in FIG. 2) may direct the operation of the RF transceiver circuit 300A, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

### Example Mixer IIP2 Calibration with a Single Baseband Tone

A radio receiver (e.g., the RX path 304 of FIG. 3) may be designed to meet specifications for second-order input intercept point (IIP2). IIP2 is a measure of linearity that quantifies second-order distortion generated by nonlinearity of circuits such as amplifiers and mixers. In a receiver, second-order intermodulation (IM2) tones may be generated by jammers of different types, such as an out-of-band (OOB) jammer or a transmit leakage signal (e.g., from the TX path 302), although mixers may be the main contributors to IM2. IIP2 may be calculated from the strength of IM2 tones. IM2 tone strength (and thus, IIP2 performance) may be dependent on a transmit (TX) bandwidth (or the bandwidth of a jammer corresponding to a transmit leakage signal) and TX-to-RX frequency offset (or jammer to in-band offset). This is because a downconverted transmit signal (e.g., a jammer) at an interface between a mixer and a baseband filter may vary depending on the TX bandwidth and the TX-to-RX offset. Hence, it may be desirable to perform IIP2 calibration by taking into account the TX bandwidth and the TX-to-RX offset.

IIP2 may be measured by modulating a local oscillator (LO) signal with a modulating signal to generate an amplitude modulated (AM) signal, downconverting the AM signal to baseband, correlating the downconverted signal with the modulating signal, and determining IIP2 based on the correlation results. IIP2 may be improved by adjusting gate bias voltages of transistors having nonlinearity that affects IIP2.

Zero-intermediate frequency (ZIF) systems (also known as direct-conversion systems) are well known to be susceptible to second-order intermodulation distortion (IMD2). Transmission jammers generate IMD2 products in the ZIF mixer. The IMD2 products may fall in-band and cause receiver desensitization.

It may be desirable to calibrate a receiver (e.g., during normal operation in the field) in order to ensure good performance even in the presence of variations in IC process, temperature, power supply voltage, etc. It may also be desirable to calibrate a receiver with as little additional hardware as possible in order to reduce cost, circuit area, etc.

Some systems use a dedicated calibration circuit to correct the IMD2 products at the baseband output. The active mixer in these systems may sense the common-mode IMD2 product to provide calibration via a calibrated feedforward path to in-phase (I) and quadrature (Q) baseband ports. The feedforward calibration “guesses” (in a feedforward fashion) the effective feedthrough of the mixer.

Some systems use an IMD2 calibration circuit that seeks to correct the IMD2 mismatch and minimize the IMD2-feedthrough of the mixer by adjusting the mixer gate voltages. Unfortunately, the calibration time is band-dependent. Additionally, these systems use two RF tones and port switching, which further add to the test time and associated cost.

Certain aspects of the present disclosure provide techniques and apparatus for mixer IIP2 calibration that decrease test time and/or reduce lateral area (e.g., footprint) of the system compared to other IIP2 calibration techniques. One technique involves applying a single baseband tone to an input of a mixer, such that the mixer generates a differential tone, and adjusting the mixer to minimize a power of the differential tone at the output of the mixer. Another technique involves downconverting a radio frequency (RF) signal with a mixer, amplifying IMD2 products generated by the mixer and fed in reverse from an output port of the mixer to an RF port of the mixer, and adjusting the mixer based on the amplified IMD2 products.

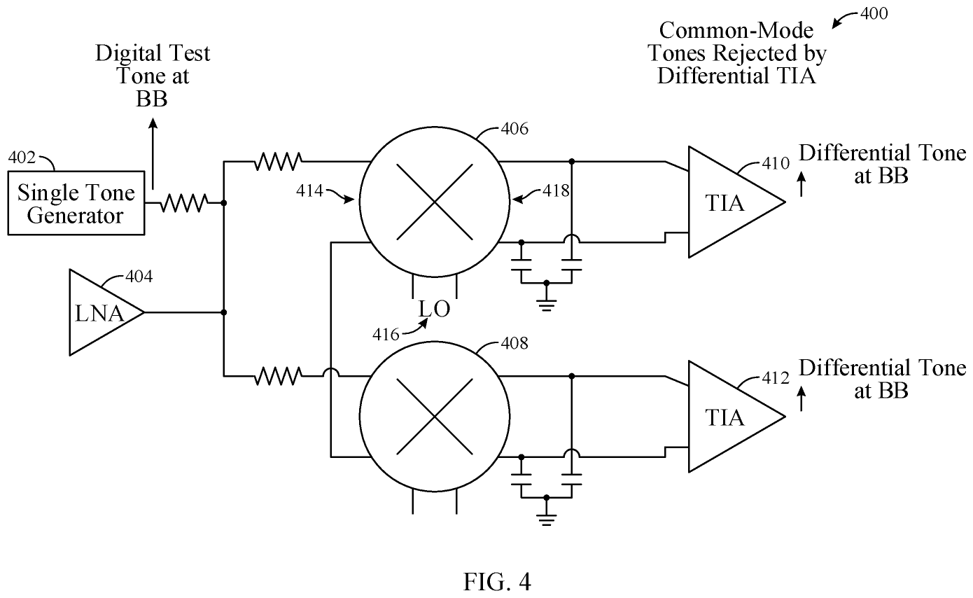

FIG. 4 is a block diagram of a circuit 400 for mixer IIP2 calibration, in which aspects of the present disclosure may be practiced. The circuit 400 includes a single tone generator 402 and at least one receive chain (e.g., RX path 304). As illustrated in FIG. 4, a first receive chain includes an amplifier 404, a mixer 406, and an amplifier 410. The input of the amplifier 404 may be coupled to at least one antenna (e.g., antenna(s) 306) via an interface (e.g., interface 308). The output of the amplifier 404 may be coupled to a first input (e.g., an RF port 414) of the mixer 406, whereas a frequency synthesizer (e.g., RX frequency synthesizer 332) may be coupled to a second input (e.g., a local oscillator (LO) port 416) of the mixer 406. An output (e.g., an output port 418) of the mixer 406 may be coupled to an input of the amplifier 410. Although certain resistive elements and capacitive elements are shown in FIG. 4, it is to be understood that at least some of these elements may be optional or may be replaced with other components.

For certain aspects, the circuit 400 may include a second receive chain. The second receive chain includes the amplifier 404, a mixer 408, and an amplifier 412. The output of the amplifier 404 may be coupled to a first input of the mixer 408, whereas the same or a different frequency synthesizer may be coupled to a second input of the mixer 408. An output of the mixer 408 may be coupled to an input of the amplifier 412. Although two receive chains are illustrated in FIG. 4, it is to be understood that there may be more or less than two receive chains.

Each of the mixers 406, 408 may be, for example, a single-balanced mixer, a double-balanced mixer, an active mixer, or any other suitable type of mixer. Each of the mixers 406, 408 may include an RF port 414, an LO port 416, and an output port 418 and may be representative of the mixer 326 in FIG. 3. The amplifier 404 may be a low noise amplifier (e.g., LNA 324), for example. The amplifier 410 and/or the amplifier 412 may be a transimpedance amplifier (TIA), as illustrated in FIG. 4.

The single tone generator 402 has an output coupled to the output of the amplifier 404, to the input of the mixer 406, and to the input of the mixer 408. For certain aspects, the single tone generator 402 may be an on-chip generator, included in the same integrated circuit (IC) as the amplifier 404, the mixer 406, and the amplifier 410. For other aspects, the single tone generator 402 may be an external generator, external to the IC with the amplifier 404, the mixer 406, and the amplifier 410. In this case, the IC may have an input/output (I/O) pin for coupling to the single tone generator 402. For certain aspects, an input of the single tone generator 402 may be coupled to an output of a frequency synthesizer (e.g., RX frequency synthesizer 332 or TX frequency synthesizer 320). In this case, the single tone generator may include one or more frequency dividers (and other components) for generating an output tone from the frequency synthesizer. For other aspects, the single tone generator 402 may be an independent frequency synthesizer.

The single tone generator 402 may be configured to generate a calibration signal having a single baseband tone. The single baseband tone may have a frequency no greater than 50 MHz for certain aspects, than 10 MHz for other aspects, or than 5 MHz for still other aspects. As an example, the single tone generator 402 may be configured to output a calibration tone at 1.2 MHz. For certain aspects, the single tone generator 402 is configured to generate a digital calibration tone (e.g., a rail-to-rail square wave having a fundamental frequency at the baseband frequency of the single baseband tone).

When the baseband tone from the single tone generator 402 is applied to the RF port 414 of the mixer 406 (or mixer 408) during IIP2 calibration, the mixer will generate common-mode IMD2 at the RF port and a differential baseband tone at the output port 418. Control logic (e.g., controller 336) may control adjustment of the mixer to minimize, or at least reduce, the power of the differential baseband tone at the output of the mixer. In other words, the mixer may be calibrated to have zero (or very little) RF feedthrough. For certain aspects, adjusting the mixer may involve changing one or more gate bias voltages of one or more transistors in the mixer. One or more indications of the adjustment(s) made to the mixer for IIP2 calibration (referred to as “IIP2 calibration codes”) may be stored in a memory (e.g., memory 338). In this manner, IIP2 of the mixer may be calibrated. Other mixers may be calibrated for IIP2 in the same manner, which may be performed concurrently for the different mixers. Mixer IIP2 calibration may be repeated for different frequency bands for a given mixer, and the IIP2 calibration codes for these different bands may also be stored.

Thus, instead of trying to measure IIP2, mixer IIP2 calibration is performed by balancing the mixer, which should lead to better IIP2 performance. In other words, the purpose of the baseband tone is to sense the imbalance of the mixer at the mixer's output, and then balance the mixer directly, instead of trying to offset some IIP2-translated frequency. Performing mixer IIP2 calibration in this manner with a single baseband tone avoids radio frequency mismatch effects and practically involves optimizing the common-mode-to-differential-mode conversion of the mixer. Furthermore, the mixer has common-mode rejection, and thus, a large amplitude baseband tone can be applied to the input of the mixer. In contrast, a large amplitude in-band RF signal may saturate the baseband filter (e.g., the BBF 328), such that the IMD2 products may not be capable of being measured, and a large out-of-band signal would be filtered out.

With an on-chip single tone generator, mixer IIP2 calibration may be performed in the lab, at the factory, or in the field. Mixer IIP2 calibration in the field may permit adjusting the mixer due to changes in ambient temperature, drift, or voltage. For example, the threshold voltage (Vₜₕ) mismatches in the mixer transistors may be temperature-dependent.

For certain aspects, after the IIP2 calibration codes for the mixer are stored, an RF tone (e.g., an in-band tone) may be applied to test the receive path(s) to confirm the IIP2 performance meets specification. The RF tone may be applied at the input of the amplifier 404 or to the input of the mixer(s) 406, 408. In the latter case, the RF tone may be applied by the single tone generator 402 or by a different signal generator, either on-chip or external to the IC with the receive chain(s).

### Example Mixer IIP2 Calibration Using Reverse Feedthrough Based on a Received RF Signal

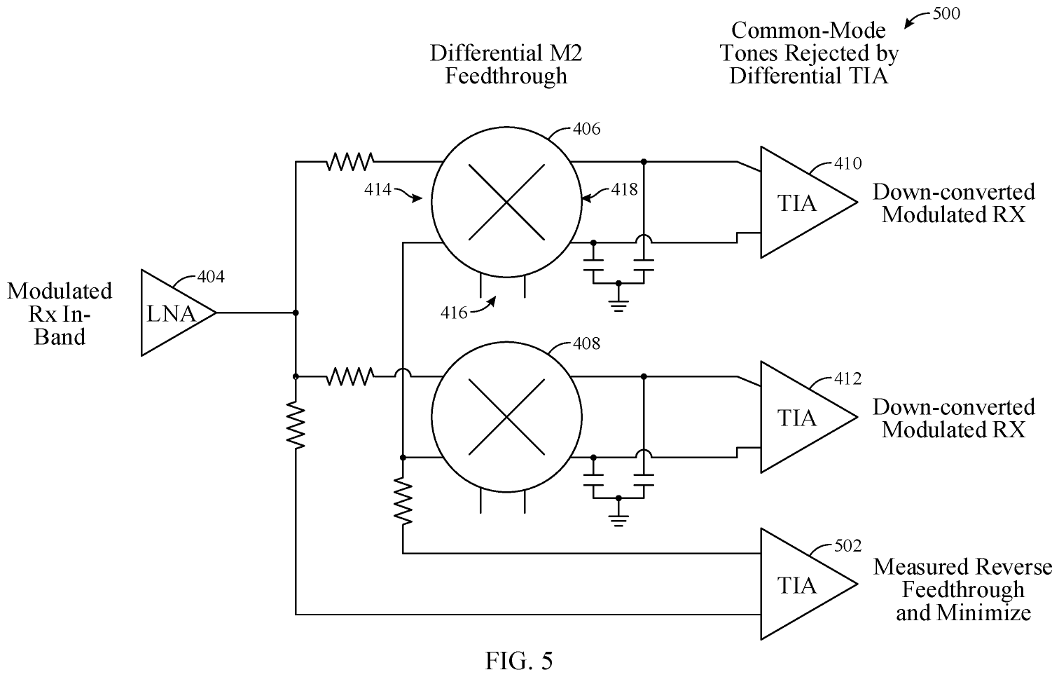

FIG. 5 is a block diagram of another circuit 500 for mixer IIP2 calibration, in accordance with certain aspects of the present disclosure. The circuit 500 includes many of the same components as the circuit 400 of FIG. 4, and much of the description of the circuit 400 applies to the circuit 500, as well, and will not be repeated here.

Compared to the circuit 400, the single tone generator may be removed, but an amplifier 502 is added to the circuit 500, forming a calibration path in addition to the normal receive chain(s). Although not shown in FIG. 5, the remainder of the calibration path may be similar to the normal receive chain(s), such as a remaining portion of the RX path 304. The amplifier 502 may have an input coupled to the output of the amplifier 404. However, there may be no mixer (and no active component) coupled between the output of the amplifier 404 and the input of the amplifier 502. In fact, the input of the amplifier 502 may be coupled directly to the output of the amplifier 404, other than traces (and in some cases passive components, such as resistors, as shown in FIG. 5) coupled therebetween. In this manner, the amplifier 502 may receive a radio frequency (RF) signal from the amplifier 404, without downconversion of the RF signal, unlike the amplifiers 410 and 412. For certain aspects, the amplifier 502 may be a TIA, as shown in FIG. 5. Although certain resistive elements and capacitive elements are shown in FIG. 5, it is to be understood that at least some of these elements may be optional or may be replaced with other components.

The circuit 500 provides for mixer IIP2 calibration by using a wirelessly received RF signal and amplifying second-order intermodulation distortion (IMD2) from reverse feedthrough (that is, baseband-to-RF) from the mixer 406 (and/or mixer 408). For example, a strong in-band RF signal may be received by the antenna (e.g., the antenna 306) coupled to the input of the amplifier 404 (in the presence of no transmission signal from the same device). The amplified RF signal may be downconverted by the mixer, thereby generating IMD2 at the RF port 414 of the mixer. The IMD2 at the RF port 414 of the mixer is considered as reverse feedthrough (from the output port 418 to the RF port 414 of the mixer). The IMD2 at the RF port of the mixer may be sensed and amplified by the amplifier 502 (without downconversion). The non-downconverted signal will be highly correlated with the downconverted signal in the normal receive chain (with the mixer), although there may be some phase offset. Calibration may be performed in a “walking algorithm” by adjusting the mixer, determining if the IMD2 increases or decreases, and leaving the mixer with an adjustment that minimizes, or at least reduces, the amplified IMD2 (e.g., minimizes the power of the amplified signal output by the amplifier 502). Other mixers may be calibrated for IIP2 in the same manner, which may be performed concurrently for the different mixers.

As described above, adjusting the mixer may involve changing one or more gate bias voltages of one or more transistors in the mixer. One or more indications of the adjustment(s) made to the mixer for IIP2 calibration may be stored in a memory (e.g., memory 338). In this manner, IIP2 of the mixer may be calibrated on-line in the field. Mixer IIP2 calibration in the field may permit adjusting the mixer due to changes in ambient temperature, drift, or voltage. Online calibration may provide for better IIP2 performance over such variations.

For certain aspects, after the IIP2 calibration codes for the mixer are stored, an RF tone (e.g., an in-band tone) may be applied to test the receive path(s) to confirm the IIP2 performance meets specification. The RF tone may be applied at the input of the amplifier 404.

### Example Mixer IIP2 Calibration Using Reverse Feedthrough Based on a Single RF Tone

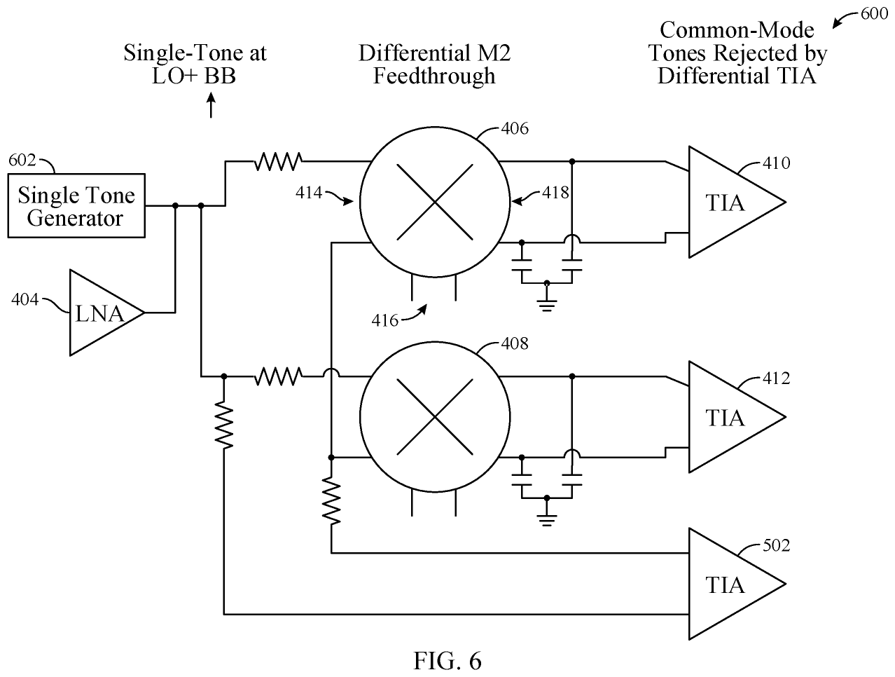

FIG. 6 is a block diagram of another circuit 600 for mixer IIP2 calibration in accordance with certain aspects of the present disclosure. The circuit 600 can be considered as a combination of adding a single tone generator 602 to the circuit 500. The circuit 600 includes many of the same components as the circuits 400 and 500 of FIGS. 4 and 5, and much of the description of the circuits 400 and 500 applies to the circuit 600, as well, and will not be repeated here. Although certain resistive elements and capacitive elements are shown in FIG. 6, it is to be understood that at least some of these elements may be optional or may be replaced with other components.

The single tone generator 602 has an output coupled to the output of the amplifier 404, to the input of the mixer 406, to the input of the mixer 408, and to the input of the amplifier 502. For certain aspects, the single tone generator 602 may be an on-chip generator, included in the same integrated circuit (IC) as the amplifier 404, the receive chain(s), and the amplifier 502. For other aspects, the single tone generator 602 may be an external generator, external to the IC with the amplifier 404, the receive chain(s), and the amplifier 502. In the latter case, the IC may have an input/output (I/O) pin for coupling to the single tone generator 602. For certain aspects, an input of the single tone generator 602 may be coupled to an output of a frequency synthesizer (e.g., RX frequency synthesizer 332 or TX frequency synthesizer 320). In this case, the single tone generator may include one or more frequency dividers (and other components) for generating an output tone from the frequency synthesizer. For other aspects, the single tone generator 602 may be an independent frequency synthesizer.

The single tone generator 602 may be configured to generate a calibration signal having a single RF tone. The single RF tone may have a frequency that is the sum of a local oscillator (LO) frequency and a baseband frequency. The LO frequency may be the frequency of the LO signal used for the mixer. The baseband frequency may be no greater than 50 MHz for certain aspects, than 10 MHz for other aspects, or than 5 MHz for still other aspects. As an example, the single tone generator 602 may be configured to output a calibration tone at LO+1.2 MHz. For certain aspects, the single tone generator 602 is configured to generate a digital calibration tone (e.g., a rail-to-rail square wave having a fundamental frequency at the frequency of the single RF tone).

Mixer IIP2 calibration with the circuit 600 may be similar to mixer IIP2 calibration with the circuit 500, except that the single RF tone from the single tone generator 602 is applied to the input of the mixer(s), rather than a wirelessly received RF signal. In other words, the single RF tone is downconverted by the mixer(s) (using an LO signal at the LO frequency applied at the LO port 416 of the mixer), generating IMD2 at the RF port(s) 414 of the mixer(s), and this reverse feedthrough signal is sensed and amplified by the amplifier 502 (without downconversion). The non-downconverted signal will be highly correlated with the downconverted signal(s) in the receive chain(s) (with the mixer(s)). Calibration may be performed in a “walking algorithm” by adjusting the mixer(s), determining if the IMD2 increases or decreases, and leaving each of the mixers with an adjustment that minimizes the amplified IMD2. Other mixers may be calibrated for IIP2 in the same manner, which may be performed concurrently for the different mixers.

For certain aspects, after the IIP2 calibration codes for the mixer are stored, an RF tone (e.g., an in-band tone) may be applied to test the receive path(s) to confirm the IIP2 performance meets specification. The RF tone may be applied at the input of the amplifier 404 or to the input of the mixer(s) 406, 408. In the latter case, the RF tone may be applied by the single tone generator 602 or by a different signal generator, either on-chip or external to the IC with the receive chain(s).

### Example Mixer IIP2 Calibration Operations

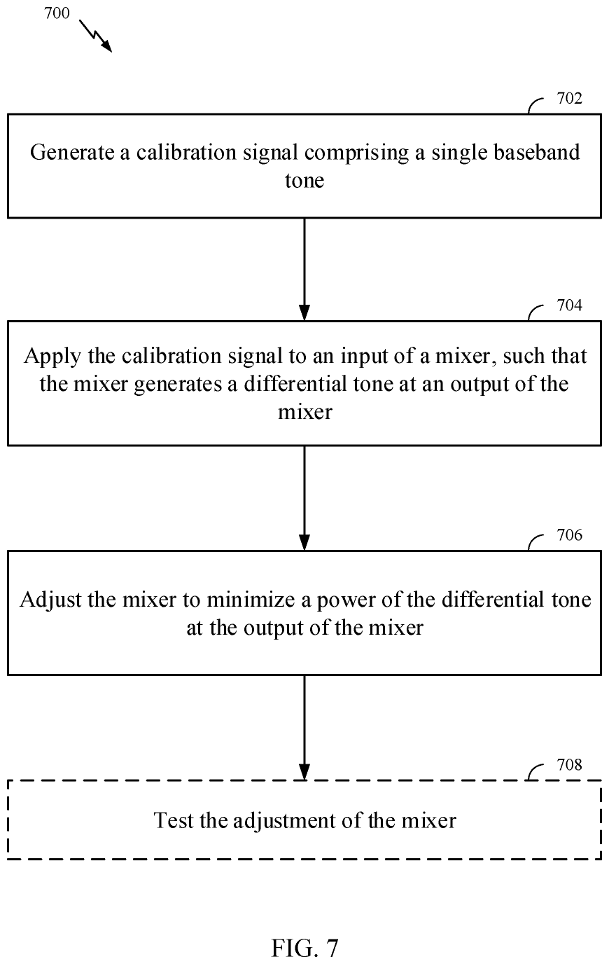

FIG. 7 is a flow diagram of example operations 700 for calibrating a mixer (e.g., for second-order input intercept point (IIP2)), in accordance with certain aspects of the present disclosure. The operations 700 may be performed, for example, by a circuit for mixer IIP2 calibration (e.g., the circuit 400 of FIG. 4).

The operations 700 may begin, at block 702, by generating (e.g., with an (on-chip) single tone generator or a frequency synthesizer) a calibration signal comprising a single baseband tone. The single baseband tone may have a frequency no greater than 50 MHz for certain aspects, than 10 MHz for other aspects, or than 5 MHz for still other aspects. At block 704, the calibration signal is applied to an input (e.g., RF port 414) of a mixer (e.g., mixer 406 or 408), and the mixer generates a differential tone at an output (e.g., output port 418) of the mixer. At block 706, the mixer is adjusted (e.g., by control logic, such as the controller 336), for example, in an effort to minimize a power of the differential tone at the output of the mixer.

According to certain aspects, the calibration signal is generated by a single tone generator (e.g., single tone generator 402). For certain aspects, the mixer and the single tone generator are part of the same integrated circuit (IC).

According to certain aspects, the calibration signal is a square wave (e.g., a rail-to-rail square wave) having a fundamental frequency as the single baseband tone.

According to certain aspects, the operations 700 further involve testing the adjustment of the mixer at optional block 708. In this case, the testing may include: applying (e.g., with an (on-chip) single tone generator or a frequency synthesizer) a test signal comprising a single radio frequency (RF) tone to the input of the mixer or to an input of an amplifier (e.g., amplifier 404 or LNA 324) having an output coupled to the input of the mixer; and determining (e.g., with a processor, such as the controller 336) whether a second-order intermodulation distortion (IMD2) performance with the single RF tone meets a predefined specification.

According to certain aspects, adjusting the mixer at block 706 includes adjusting at least one gate bias voltage of at least one transistor in the mixer.

According to certain aspects, adjusting the mixer at block 706 involves adjusting the mixer to have no significant feedthrough of the single baseband tone at the output of the mixer.

According to certain aspects, the mixer is a single-balanced mixer or a double-balanced mixer. For other aspects, the mixer is an active mixer.

According to certain aspects, the operations 700 further involve storing (e.g., in a memory, such as memory 338) one or more indications (e.g., IIP2 calibration codes) based on the adjustment of the mixer at block 706.

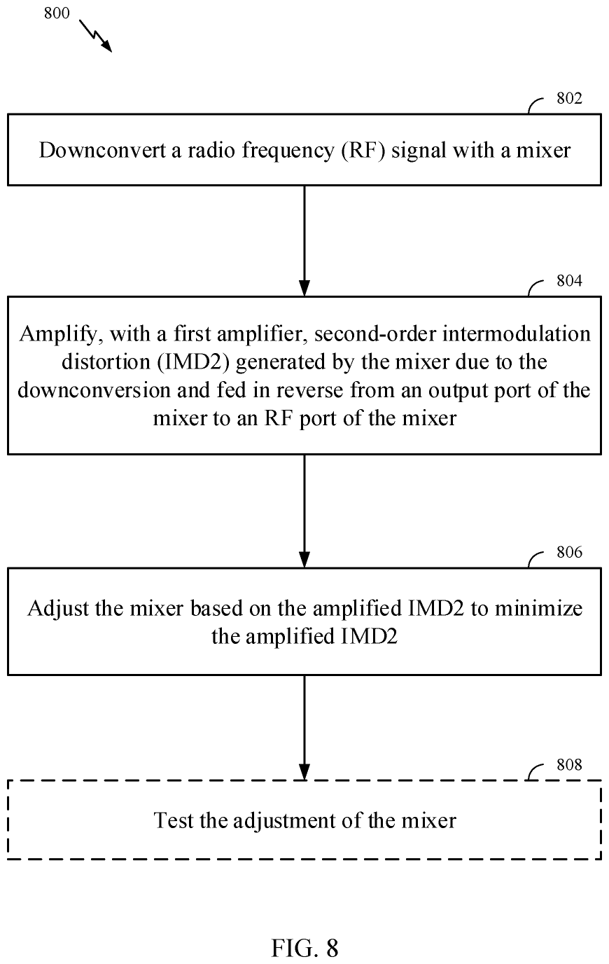

FIG. 8 is a flow diagram of example operations 800 for calibrating a mixer (e.g., for second-order input intercept point (IIP2)), in accordance with certain aspects of the present disclosure. The operations 800 may be performed, for example, by a circuit for mixer IIP2 calibration (e.g., the circuit 500 of FIG. 5 or the circuit 600 of FIG. 6).

The operations 800 may generally begin, at block 802, with a mixer (e.g., mixer 406 or mixer 408) downconverting a radio frequency (RF) signal. At block 804, a first amplifier (e.g., amplifier 502) may amplify second-order intermodulation distortion (IMD2) generated by the mixer due to the downconversion at block 802 and fed in reverse from an output port (e.g., output port 418) of the mixer to an RF port (e.g., RF port 414) of the mixer. At block 806, the circuit (e.g., control logic, such as the controller 336) may adjust the mixer based on the amplified IMD2 (e.g., in an effort to minimize the amplified IMD2).

According to certain aspects, the operations 800 further include an antenna (e.g., antenna 306) receiving the RF signal (e.g., a strong receive signal), and a second amplifier (e.g., amplifier 404) amplifying the RF signal before the downconverting at block 802. In this manner, on-line calibration of the mixer may be performed, such that the mixer may be adjusted for changes in temperature during regular operation in the field.

According to certain aspects, the operations further involve: generating (e.g., with an (on-chip) single tone generator or a frequency divider) a calibration signal comprising a single tone at a sum of a local oscillator (LO) frequency and a baseband frequency; and applying the calibration signal to an RF port (e.g., RF port 414) of the mixer and an LO signal at the LO frequency to an LO port (e.g., LO port 416) of the mixer. In this case, the calibration signal is the RF signal for downconverting with the mixer at block 802. For certain aspects, the calibration signal is generated by a single tone generator (e.g., single tone generator 602). In this case, the mixer and the single tone generator may be part of the same integrated circuit (IC). The calibration signal may be a square wave (e.g., a rail-to-rail square wave) having a fundamental frequency as the single tone. The baseband frequency may be no greater than 50 MHz for certain aspects, than 10 MHz for other aspects, or than 5 MHz for still other aspects.

According to certain aspects, the adjusting at block 806 includes adjusting the mixer for changes in temperature.

According to certain aspects, the adjusting at block 806 involves adjusting at least one gate bias voltage of at least one transistor in the mixer.

According to certain aspects, the operations 800 further include testing the adjustment of the mixer at optional block 808. In this case, testing the adjustment of the mixer may involve: applying (e.g., with an (on-chip) single tone generator or a frequency synthesizer) a test signal comprising a single RF tone to the RF port of the mixer or to an input of a second amplifier (e.g., amplifier 404 or LNA 324) having an output coupled to the RF port of the mixer; and determining (e.g., with a processor, such as the controller 336) whether an IMD2 performance with the single RF tone meets a predefined specification.

According to certain aspects, the mixer is a single-balanced mixer or a double-balanced mixer.

According to certain aspects, the operations 800 further involve storing (e.g., in a memory, such as memory 338) one or more indications (e.g., IIP2 calibration codes) based on the adjustment of the mixer at block 806.

### Example Aspects

In addition to the various aspects described above, specific combinations of aspects are within the scope of the present disclosure, some of which are detailed below:
Aspect 1: A circuit for mixer second-order input intercept point (IIP2) calibration, the circuit comprising: a first receive chain comprising a first mixer; and a single tone generator having an output coupled to an input of the first mixer and configured to generate a calibration signal having a single baseband tone.
Aspect 2: The circuit of Aspect 1, wherein the circuit is an integrated circuit (IC) and wherein the IC includes the first receive chain and the single tone generator
Aspect 3: The circuit of Aspect 1 or 2, wherein the first receive chain further comprises a first amplifier having an output coupled to the input of the first mixer and to the output of the single tone generator.
Aspect 4: The circuit of Aspect 3, wherein the first receive chain further comprises a second amplifier having an input coupled to an output of the first mixer.
Aspect 5: The circuit of Aspect 3 or 4, further comprising a second receive chain comprising the first amplifier and a second mixer, wherein an input of the second mixer is coupled to the output of the first amplifier and to the output of the single tone generator.
Aspect 6: The circuit of any of Aspects 1 to 5, wherein the first mixer comprises a single-balanced mixer or a double-balanced mixer.
Aspect 7: The circuit of any of Aspects 1 to 6, wherein the single tone generator is configured to generate a rail-to-rail square wave having a fundamental frequency as the single baseband tone for the calibration signal.
Aspect 8: The circuit of any of Aspects 1 to 7, wherein the single tone generator comprises a frequency divider.
Aspect 9: The circuit of any of Aspects 1 to 8, wherein the single baseband tone has a frequency no greater than 5 MHz.
Aspect 10: A wireless device comprising the circuit of any of Aspects 1 to 9, the wireless device further comprising: at least one antenna coupled to an input of the first receive chain; an analog-to-digital converter coupled to an output of the first receive chain; and a processor having an input coupled to an output of the analog-to-digital converter, wherein the first mixer is configured to generate a differential tone when the single tone generator applies the calibration signal to the first mixer and wherein the processor is configured to receive a representation of the differential tone, to control the single tone generator, and to control adjustment of the first mixer to minimize a power of the representation of the differential tone.
Aspect 11: A method of mixer second-order input intercept point (IIP2) calibration, the method comprising: generating a calibration signal comprising a single baseband tone; applying the calibration signal to an input of a mixer, such that the mixer generates a differential tone at an output of the mixer; and adjusting the mixer to minimize a power of the differential tone at the output of the mixer.
Aspect 12: The method of Aspect 11, wherein the calibration signal is generated by a single tone generator and wherein the mixer and the single tone generator are part of a same integrated circuit (IC).
Aspect 13: The method of Aspect 11 or 12, further comprising testing the adjustment of the mixer, wherein the testing comprises: applying a test signal comprising a single radio frequency (RF) tone to the input of the mixer or to an input of an amplifier having an output coupled to the input of the mixer; and determining whether a second-order intermodulation distortion (IMD2) performance with the single RF tone meets a predefined specification.
Aspect 14: The method of any of Aspects 11 to 13, wherein the calibration signal is a rail-to-rail square wave having a fundamental frequency as the single baseband tone.
Aspect 15: The method of any of Aspects 11 to 14, wherein the single baseband tone has a frequency no greater than 5 MHz.
Aspect 16: The method of any of Aspects 11 to 15, wherein adjusting the mixer comprises adjusting at least one gate bias voltage of at least one transistor in the mixer.
Aspect 17: The method of any of Aspects 11 to 16, wherein adjusting the mixer comprises adjusting the mixer to have no significant feedthrough of the single baseband tone at the output of the mixer.
Aspect 18: A circuit for mixer second-order input intercept point (IIP2) calibration, the circuit comprising: a first amplifier; a first receive chain comprising a first mixer having an input coupled to an output of the first amplifier; and a second amplifier having an input coupled to the output of the first amplifier.
Aspect 19: The circuit of Aspect 18, wherein the circuit lacks a mixer coupled between the first amplifier and the second amplifier.
Aspect 20: The circuit of Aspect 18 or 19, wherein the first mixer is configured to downconvert a radio frequency (RF) signal to a baseband signal and wherein the second amplifier is configured to receive a reverse feedthrough signal from the input of the first mixer.
Aspect 21: The circuit of any of Aspects 18 to 20, further comprising a single tone generator having an output coupled to the output of the first amplifier, to the input of the first mixer, and to the input of the second amplifier, the single tone generator being configured to generate a calibration signal having a single tone at a sum of a local oscillator (LO) frequency and a baseband frequency.
Aspect 22: The circuit of Aspect 21, wherein the circuit is an integrated circuit (IC) and wherein the IC includes the first amplifier, the first receive chain, the second amplifier, and the single tone generator.
Aspect 23: The circuit of Aspect 21 or 22, further comprising a second receive chain comprising: the first amplifier; and a second mixer having an input coupled to the output of the first amplifier, to the input of the second amplifier, and to the output of the single tone generator.
Aspect 24: The circuit of any of Aspects 21 to 23, wherein the single tone generator is configured to generate a rail-to-rail square wave having a fundamental frequency as the single tone for the calibration signal.
Aspect 25: The circuit of any of Aspects 21 to 24, wherein the LO frequency is a radio frequency and wherein the baseband frequency is no greater than 5 MHz.
Aspect 26: A wireless device comprising the circuit of any of Aspects 21 to 25, the wireless device further comprising: a frequency synthesizer configured to generate an LO signal at the LO frequency and to apply the LO signal to an LO port of the first mixer; an analog-to-digital converter coupled to an output of the first receive chain; and a processor having an input coupled to an output of the analog-to-digital converter, wherein: the single tone generator is configured to apply the calibration signal to a radio frequency (RF) port of the first mixer; the first mixer is configured to downconvert the calibration signal based on the LO signal; the second amplifier is configured to amplify second-order intermodulation distortion (IMD2) generated by the first mixer due to the downconversion; and the processor is configured to control adjustment of the first mixer based on the amplified IMD2 to minimize the amplified IMD2.
Aspect 27: A wireless device comprising the circuit of any of Aspects 18 to 20, the wireless device further comprising: at least one antenna coupled to an input of the first receive chain; an analog-to-digital converter coupled to an output of the first receive chain; and a processor having an input coupled to an output of the analog-to-digital converter, wherein: the at least one antenna is configured to receive a radio frequency (RF) signal; the first amplifier is configured to amplify the received RF signal; the first mixer is configured to downconvert the amplified RF signal; the second amplifier is configured to amplify second-order intermodulation distortion (IMD2) generated by the first mixer due to the downconversion; and the processor is configured to control adjustment of the first mixer based on the amplified IMD2.
Aspect 28: The circuit of any of Aspects 18 to 27, wherein the first mixer comprises a single-balanced mixer or a double-balanced mixer.
Aspect 29: A method of mixer second-order input intercept point (IIP2) calibration, the method comprising: downconverting a radio frequency (RF) signal with a mixer; amplifying, with a first amplifier, second-order intermodulation distortion (IMD2) generated by the mixer due to the downconversion and fed in reverse from an output port of the mixer to an RF port of the mixer; and adjusting the mixer based on the amplified IMD2 to minimize the amplified IMD2.
Aspect 30: The method of Aspect 29, further comprising: receiving the RF signal with an antenna; and amplifying the RF signal with a second amplifier before the downconverting.
Aspect 31: The method of Aspect 29, further comprising: generating a calibration signal comprising a single tone at a sum of a local oscillator (LO) frequency and a baseband frequency; and applying the calibration signal to an RF port of the mixer and an LO signal at the LO frequency to an LO port of the mixer, wherein the calibration signal is the RF signal for the downconverting with the mixer.
Aspect 32: The method of Aspect 31, wherein the calibration signal is generated by a single tone generator and wherein the mixer and the single tone generator are part of a same integrated circuit (IC).
Aspect 33: The method of Aspect 31 or 32, wherein the calibration signal is a rail-to-rail square wave having a fundamental frequency as the single tone.
Aspect 34: The method of any of Aspects 31 to 33, wherein the baseband frequency is no greater than 5 MHz.
Aspect 35: The method of any of Aspects 29 to 34, wherein the adjusting comprises adjusting the mixer for changes in temperature.
Aspect 36: The method of any of Aspects 29 to 35, wherein the adjusting comprises adjusting at least one gate bias voltage of at least one transistor in the mixer.
Aspect 37: The method of any of Aspects 29 to 36, further comprising testing the adjustment of the mixer, wherein the testing comprises: applying a test signal comprising a single RF tone to the RF port of the mixer or to an input of a second amplifier having an output coupled to the RF port of the mixer; and determining whether an IMD2 performance with the single RF tone meets a predefined specification.

### Additional Considerations

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components. For example, means for generating a calibration signal may include a frequency synthesizer, such as the TX frequency synthesizer 320 or the RX frequency synthesizer 332 of FIG. 3, or a single tone generator, such as the single tone generator 402 or 602 of FIG. 4 or 6. Means for applying the calibration signal may include one or more traces, connectors, cables, resistors, and/or an RF port, such as the RF port 414 of FIG. 4, 5 or 6. Means for adjusting may include control logic, such as the controller 336 of FIG. 3. Means for downconverting may include a mixer, such as the mixer 406 or 408 of FIG. 4, 5 or 6. Means for amplifying may include an amplifier, such as the amplifier 502 of FIG. 5 or 6.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. A circuit for mixer second-order input intercept point (IIP2) calibration, the circuit comprising:
a first receive chain comprising a first mixer; and
a single tone generator having an output coupled to an input of the first mixer and configured to generate a calibration signal having a single baseband tone.

2. The circuit of claim 1, wherein the circuit is an integrated circuit (IC) and wherein the IC includes the first receive chain and the single tone generator.

3. The circuit of claim 1, wherein the first receive chain further comprises a first amplifier having an output coupled to the input of the first mixer and to the output of the single tone generator.

4. The circuit of claim 3, wherein the first receive chain further comprises a second amplifier having an input coupled to an output of the first mixer.

5. The circuit of claim 3, further comprising a second receive chain comprising the first amplifier and a second mixer, wherein an input of the second mixer is coupled to the output of the first amplifier and to the output of the single tone generator.

6. The circuit of claim 1, wherein the first mixer comprises a single-balanced mixer or a double-balanced mixer.

7. The circuit of claim 1, wherein the single tone generator is configured to generate a rail-to-rail square wave having a fundamental frequency as the single baseband tone for the calibration signal.

8. The circuit of claim 1, wherein the single tone generator comprises a frequency divider.

9. The circuit of claim 1, wherein the single baseband tone has a frequency no greater than 5 MHz.

10. A wireless device comprising the circuit of claim 1, the wireless device further comprising:
at least one antenna coupled to an input of the first receive chain;
an analog-to-digital converter coupled to an output of the first receive chain; and
a processor having an input coupled to an output of the analog-to-digital converter, wherein the first mixer is configured to generate a differential tone when the single tone generator applies the calibration signal to the first mixer and wherein the processor is configured to receive a representation of the differential tone, to control the single tone generator, and to control adjustment of the first mixer to minimize a power of the representation of the differential tone.

11. A method of mixer second-order input intercept point (IIP2) calibration, the method comprising:
generating a calibration signal comprising a single baseband tone;
applying the calibration signal to an input of a mixer, such that the mixer generates a differential tone at an output of the mixer; and
adjusting the mixer to minimize a power of the differential tone at the output of the mixer.

12. The method of claim 11, wherein the calibration signal is generated by a single tone generator and wherein the mixer and the single tone generator are part of a same integrated circuit (IC).

13. The method of claim 11, further comprising testing the adjustment of the mixer, wherein the testing comprises:
applying a test signal comprising a single radio frequency (RF) tone to the input of the mixer or to an input of an amplifier having an output coupled to the input of the mixer; and
determining whether a second-order intermodulation distortion (IMD2) performance with the single RF tone meets a predefined specification.

14. The method of claim 11, wherein the calibration signal is a rail-to-rail square wave having a fundamental frequency as the single baseband tone.

15. The method of claim 11, wherein the single baseband tone has a frequency no greater than 5 MHz.

16. The method of claim 11, wherein adjusting the mixer comprises adjusting at least one gate bias voltage of at least one transistor in the mixer.

17. The method of claim 11, wherein adjusting the mixer comprises adjusting the mixer to have no significant feedthrough of the single baseband tone at the output of the mixer.

18. A circuit for mixer second-order input intercept point (IIP2) calibration, the circuit comprising:
a first amplifier;
a first receive chain comprising a first mixer having an input coupled to an output of the first amplifier; and
a second amplifier having an input coupled to the output of the first amplifier.

19. The circuit of claim 18, wherein the circuit lacks a mixer coupled between the first amplifier and the second amplifier.

20. The circuit of claim 18, wherein the first mixer is configured to downconvert a radio frequency (RF) signal to a baseband signal and wherein the second amplifier is configured to receive a reverse feedthrough signal from the input of the first mixer.

21. The circuit of claim 18, further comprising a single tone generator having an output coupled to the output of the first amplifier, to the input of the first mixer, and to the input of the second amplifier, the single tone generator being configured to generate a calibration signal having a single tone at a sum of a local oscillator (LO) frequency and a baseband frequency.

22. The circuit of claim 21, wherein the circuit is an integrated circuit (IC) and wherein the IC includes the first amplifier, the first receive chain, the second amplifier, and the single tone generator.

23. The circuit of claim 21, further comprising a second receive chain comprising:
the first amplifier; and
a second mixer having an input coupled to the output of the first amplifier, to the input of the second amplifier, and to the output of the single tone generator.

24. The circuit of claim 21, wherein the single tone generator is configured to generate a rail-to-rail square wave having a fundamental frequency as the single tone for the calibration signal.

25. The circuit of claim 21, wherein the LO frequency is a radio frequency and wherein the baseband frequency is no greater than 5 MHz.

26. A wireless device comprising the circuit of claim 21, the wireless device further comprising:
a frequency synthesizer configured to generate an LO signal at the LO frequency and to apply the LO signal to an LO port of the first mixer;
an analog-to-digital converter coupled to an output of the first receive chain; and
a processor having an input coupled to an output of the analog-to-digital converter, wherein:
the single tone generator is configured to apply the calibration signal to a radio frequency (RF) port of the first mixer;
the first mixer is configured to downconvert the calibration signal based on the LO signal;
the second amplifier is configured to amplify second-order intermodulation distortion (IMD2) generated by the first mixer due to the downconversion; and
the processor is configured to control adjustment of the first mixer based on the amplified IMD2 to minimize the amplified IMD2.

27. A wireless device comprising the circuit of claim 18, the wireless device further comprising:
at least one antenna coupled to an input of the first receive chain;
an analog-to-digital converter coupled to an output of the first receive chain; and
a processor having an input coupled to an output of the analog-to-digital converter, wherein:
the at least one antenna is configured to receive a radio frequency (RF) signal;
the first amplifier is configured to amplify the received RF signal;
the first mixer is configured to downconvert the amplified RF signal;
the second amplifier is configured to amplify second-order intermodulation distortion (IMD2) generated by the first mixer due to the downconversion; and
the processor is configured to control adjustment of the first mixer based on the amplified IMD2.

28. The circuit of claim 18, wherein the first mixer comprises a single-balanced mixer or a double-balanced mixer.

29. A method of mixer second-order input intercept point (IIP2) calibration, the method comprising:
downconverting a radio frequency (RF) signal with a mixer;
amplifying, with a first amplifier, second-order intermodulation distortion (IMD2) generated by the mixer due to the downconversion and fed in reverse from an output port of the mixer to an RF port of the mixer; and
adjusting the mixer based on the amplified IMD2 to minimize the amplified IMD2.

30. The method of claim 29, further comprising:
receiving the RF signal with an antenna; and
amplifying the RF signal with a second amplifier before the downconverting.

31. The method of claim 29, further comprising:
generating a calibration signal comprising a single tone at a sum of a local oscillator (LO) frequency and a baseband frequency; and
applying the calibration signal to an RF port of the mixer and an LO signal at the LO frequency to an LO port of the mixer, wherein the calibration signal is the RF signal for the downconverting with the mixer.

32. The method of claim 31, wherein the calibration signal is generated by a single tone generator and wherein the mixer and the single tone generator are part of a same integrated circuit (IC).

33. The method of claim 31, wherein the calibration signal is a rail-to-rail square wave having a fundamental frequency as the single tone.

34. The method of claim 31, wherein the baseband frequency is no greater than 5 MHz.

35. The method of claim 29, wherein the adjusting comprises adjusting the mixer for changes in temperature.

36. The method of claim 29, wherein the adjusting comprises adjusting at least one gate bias voltage of at least one transistor in the mixer.

37. The method of claim 29, further comprising testing the adjustment of the mixer, wherein the testing comprises:
applying a test signal comprising a single RF tone to the RF port of the mixer or to an input of a second amplifier having an output coupled to the RF port of the mixer; and
determining whether an IMD2 performance with the single RF tone meets a predefined specification.
